(19) United States
(12) Patent Application Publication
(10) Pub. No.: US 2005/0193159 A1
(43) Pub. Date: Sep. 1, 2005

(54) Embedded power control circuitry for a portable disk drive carrier having a hot-plug application

(76) Inventors: Yiu-Keung Ng, Monterey Park, CA (US); Dieter G. Paul, Anaheim, CA (US)

Correspondence Address: MORLAND C FISCHER, 2030 MAIN ST, SUITE 1050, IRVINE, CA, 92614, US

(21) Appl. No.: 10/789,763

(22) Filed: Mar. 1, 2004

(51) Int. Cl. H05K 1/00; G06F 12/00; G06F 13/00

(52) U.S. Cl. 710/302; 361/685; 439/60; 711/112

(57) ABSTRACT

A portable carrier for a disk drive including power control circuitry to enable a hot-plug connection between an external connector on the carrier and an opposing carrier mating connector on the back panel of an enclosure of a data storage system of the kind that is typically part of a file server, so that the disk drive can be powered from 5 and 12 volt power buses within the enclosure, but without damaging the disk drive or the opposing connectors at the moment of contact therebetween as a consequence of a current surge. The power control circuitry includes a timer and 5 volt and 12 volt carrier power switches (e.g., MOSFETs) that are respectively connected between the 5 volt and 12 volt power buses of the enclosure and the disk drive. Following a particular time delay, the timer generates an ENABLE signal to cause the carrier power switches to be rendered conductive to thereby complete current paths between the 5 volt and 12 volt power buses and the disk drive so that the disk drive can operate normally and communicate with a host computer of the data storage system.

### BACKGROUND OF THE INVENTION

1. Field of the Invention

This invention relates to power control circuitry located on a portable carrier for a hot-pluggable disk drive which avoids damage to the disk drive and its connector by minimizing the effects of current surges when the disk drive is first coupled to a mating connector at the back panel of a data storage system enclosure within which power buses are housed.

2. Background Art

Hard disk drives of a data storage system are generally hot-pluggable. Therefore, it is not necessary to power down the entire system to install a disk drive that has been returned following the repair or replacement of a defective drive. The data storage system is typically part of a file server which is connected to a network at all times. All of the disk drives of the system and their associated electronics, including the power supplies to the drives, the host interface I/O boards, drive status indication electronics, disk array modules, etc. are housed in a metal enclosure (i.e., a data storage system chassis). A data storage system chassis contains a number of removable disk drive carriers, each carrier receiving a respective disk drive. The carrier protects the installed disk drive and ensures that the drive will be properly coupled to a mating connector which is located at the back panel or back plane of the system. The number of mating connectors at the back panel of the chassis is the same as the number of disk drives to be installed within the data storage system chassis.

The back panel also has connectors to be mated to incoming disk drive carriers. At the instant that a disk drive carrier makes electrical contact with its respective connector at the back panel to power the disk drive within the carrier, there is a surge of current due to the fact that current is suddenly drawn from the power supply system at the back panel to charge the decoupling capacitors associated with the disk drive. Such a surge of current during the moment of contact is known to generate an electric spark which may damage the power pins of the disk drive carrier and/or the disk drive thereof as a consequence of the sudden rush of current flowing therethrough. Moreover, the corresponding high temperature that is generated by the electric spark can damage the disk drive as well as its mating connector at the back panel.

To overcome the problem caused by the surge of current during the moment of hot-plugging the disk drive carrier to a back panel, disk drives have been manufactured that are adapted for current suppression during hot-plug applications. That is, when they are connected to a specially designed back panel which is capable of supporting hot-pluggable disk drives, the current surge is reduced to a level which will not damage the power pins of the disk drive connector and the corresponding power pins of the carrier mating connector at the back panel. By way of example, disk drives which are particularly adapted to be hot-pluggable include SCSI, Fiber Channel, Serial ATA and Serial Attached SCSI.

In general, a hot-pluggable disk drive includes a connector having both long and short pins. The long pins are the power pre-charge pins and their respective ground pins are used to return the pre-charge current back to the power sources at the back panel. The short pins are used for the signals, powers and grounds. The same type of long and short pin hot pluggable mating connectors are located at the back panel, but with an opposite gender used for mating to their respective disk drives. In addition, the back panel is implemented with current limiting circuitry in electrical series with each of the pre-charge pins. The current limiting circuitry prevents the electrical sparks at the pre-charge pins when contact is first made between the pre-charge pins of the disk drive connector and the pre-charge pins at the back panel mating connector.

By way of particular example, and referring to FIG. 1 of the drawings, there is shown a block diagram to illustrate the present technique for solving the current surge problem that is faced by disk drives used in hot-plug applications. FIG. 1 depicts the back panel or back plane 1 of a data storage enclosure or chassis. In the present example, the back panel 1 accommodates 1 . . . N FC (i.e., Fiber channel) disk drives 3. Each disk drive 3 is mounted in a portable disk drive carrier 5. The connector 7 of each disk drive 3 is mated to a respective disk drive connector 9 at the back panel 1. Connectors 7 and 9 are identical in construction, but of opposite gender.

The opposing disk drive connectors 7 and 9 of the disk drive 3 and back panel 1 are especially adapted for hot-plug applications. As described above, each connector 7 and 9 includes sets of long and short pins that are interconnected with respective power buses at back panel 1. The long pins of disk drive mating connector 9 include a 5 volt pre-charge pin 10, a 12 volt pre-charge pin 12, and a ground pre-charge pin 14. The long 5 volt pre-charge pin 10 is connected to the 5 volt power bus 16 of the data storage system via 5 volt pre-charge current limiting circuitry 18. The long 12 volt pre-charge pin 12 is connected to the 12 volt power bus 20 of the system via 12 volt pre-charge current limiting circuitry 22. The long ground pre-charge pin 14 is connected directly to the ground bus 24 of the system.

The current limiting circuitry 18 and 22 are connected to the 5 volt and 12 volt power buses 16 and 20 to limit the current flowing through their respective long pre-charge pins 10 and 12. In particular, the 5 volt pre-charge current charges up the 5 volt decoupling capacitors of the disk drive 3 to 5 volts prior to the time that the short 5 volt power pin 26 of the system makes contact with its complementary pin at the disk drive connector 7. Likewise, the 12 volt pre-charge current charges up the 12 volt decoupling capacitors at the disk drive 3 to 12 volts prior to the time that the short 12 volt power pin 28 of the system makes contact with its complementary pin at the disk drive connector 7.

The short pins at the disk drive mating connector 9 at back panel 1 include the aforementioned 5 volt system power pin 26, the aforementioned 12 volt system power pin 28, a ground pin 30, and the disk drive signal interface pins (not shown). The short pins 26, 28 and 30 of disk drive mating connector 9 are connected to their complementary short pins at the disk drive connector 7 after the long pins 10, 12 and 14 have first been connected to their complementary long pins of disk drive connector 7. In general, the long 5 volt pre-charge pin associated with the disk drive connector 7 is connected directly to the short 5 volt power pin, and the long 12 volt pre-charge pin at connector 7 is connected directly to the short 12 volt power pin. Therefore, unlike the pins of disk drive mating connector 9, there is no current limiting circuitry between the pre-charge pins and their respective power pins of the connector 7 at the incoming disk drive side.

By virtue of the difference in length between the opposing long (e.g., 10, 12 and 14) and short (e.g., 26, 28 and 30) pins, the decoupling capacitors at the disk drive side will be fully charged to their respective voltage levels (e.g., 5 volts and 12 volts) during the initial contact of the long pre-charge pins. Moreover, since the long pre-charge pins and the short power pins at the disk drive side are connected directly together, the short power pins will also receive their full voltage levels.

By the time that the short power pins at the incoming disk drive side make contact with their complementary short power pins of the mating disk drive connector 9 at the back panel 1, the short power pins at the disk drive side will have already been charged to their respective voltage levels. Since the voltage levels on the short power pins at the incoming disk drive side and the complementary short power pins (e.g., 26, 28 and 30) at the mating disk drive connector 9 are identical (e.g., 5 volts, 12 volts, or ground), there will be no voltage difference and, therefore, no current flowing through the complementary pairs of short power pins at the instant of contact between the incoming connector 7 of disk drive 3 and its opposing mating connector 9 at the back panel 1. In this case, the disk drive 3 will not begin to draw current from the 5 volt and 12 volt power pins to sustain normal operation until a short time after the initial contact is made between the opposing incoming and mating disk drive connectors 7 and 9.

In some cases, there will be a small amount of current surging through the complementary pairs of short power pins at the instant of contact between the connector 7 of disk drive 3 and its opposing mating connector 9 at the back panel 1. This is due to the resistance at the short power pins at the drive connector 7 being greater than the resistance at the pre-charge pins at the drive connector 7. Thus, the short power pins have slightly lower voltages than the voltages at their respective pre-charge pins. However, in most cases, this small amount of inrushing current will not have enough energy to generate electrical sparks to damage the power pins at the drive connector 7 and at the mating connector 9 at back panel 1 during the instant of contact. Therefore, the chances of damaging the disk drive 1 during the hot-plug process is greatly reduced.

Despite the ability of the data storage system illustrated in FIG. 1 to avoid current surges and corresponding pin damage during the hot-plug connection of the disk drives to their respective mating connectors at the back panel 1, there are some data storage systems that require the integration of relatively low cost disk drives, such as a parallel ATA (PATA) drive, which are not capable of a hot-plug connection. In this same regard, the system of FIG. 1 cannot handle some carriers which are required to accommodate a hot-pluggable disk drive along with I/O circuitry which is capable of transmitting input and output disk drive data but is not a part of the disk drive. By way of example, a Serial ATA (SATA) disk drive having a port selector may have to be located on the same disk drive carrier. Although the SATA disk drive, in and of itself, may be manufactured for hot-plug application, the I/O port selector which must be hot-plugged to the back panel is typically not capable of making a hot plug connection. Consequently, the connector contact pins of the SATA disk drive as well as the complementary contact pins of the opposing mating connector at the back panel may remain susceptible to damage due to current surges at the moment of interconnection therebetween. Yet another example where the solution of FIG. 1 may prove to be ineffective is in the case where the disk drive carrier accommodates both a disk drive which is not adapted for a hot-plug connection and an electronic circuit which is not part of the disk drive. By way of example, such an independent circuit is a SATA-to-PATA converter circuit for a parallel ATA (PATA) disk drive.

### SUMMARY OF THE INVENTION

In general terms, power control circuitry is disclosed for a portable carrier within which a disk drive is housed to enable the hot-plug connection of the carrier within a data storage system enclosure (e.g., at the back panel thereof) of a data storage system of the kind that is typically part of a network file server. The power control circuitry delays the supply of power from power buses within the data storage system enclosure to the disk drive when an external connector of the disk drive carrier is detachably coupled to an opposing carrier mating connector at the back panel of the data storage system enclosure so as to avoid having to first power down the system and avoid damage to the disk drive and the opposing connector of the disk drive carrier at the back panel of the enclosure.

The power control circuitry of the portable disk drive carrier is electrically connected between the external connector of the carrier and an internal disk drive mating connector of the carrier. In the preferred embodiment, a connector of the disk drive is attached to the internal disk drive mating connector of the carrier, whereby the power control circuitry and the disk drive are interconnected with one another. The power control circuitry includes a time delay circuit by which power is supplied from the power buses at the data storage system enclosure to the disk drive at the disk drive carrier a particular time after the external carrier connector of the disk drive carrier is first coupled to the carrier mating connector at the back panel of the data storage system enclosure.

The time delay circuit of the power control circuitry includes a timer that is adapted to establish a time delay before power is supplied to the disk drive. The power control circuitry has 5 volt and 12 volt carrier switches (e.g., MOSFETs) that are respectively connected between 5 volt and 12 volt power buses at the storage system enclosure and the disk drive once the disk drive carrier is coupled to the back panel of the system enclosure. When the time delay has expired following the coupling of the external carrier connector of the disk drive carrier to the carrier mating connector at the back panel, the timer generates an ENABLE signal which is provided to each of the 5 volt and 12 volt carrier switches. The carrier switches are now rendered conductive to complete current paths between the 5 volt and 12 volt power buses and the disk drive to allow normal disk drive operation, whereby the disk drive can be accessed by the host computer. However, during the aforementioned time delay, any current surges that may have been generated when the disk drive carrier is first coupled to the back panel of the data storage system enclosure will be dissipated.

In a preferred embodiment of the invention, the disk drive that is housed within the portable disk drive carrier is a parallel ATA (PATA) disk drive. The PATA disk drive is accessed by a serial ATA (SATA) host bus adapter (HBA) by way of an HBA connector at the data storage system enclosure. Therefore, a SATA-to-PATA converter circuit is located on the disk drive carrier to convert the serial differential signal of the SATA disk drive to parallel data that is associated with a PATA disk drive. The SATA-to-PATA converter circuit is powered from the 5 volt power bus at the storage system enclosure once the 5 volt carrier switch of the power control circuitry has been rendered conductive by the ENABLE signal generated by the timer following the expiration of the time delay.

### BRIEF DESCRIPTION OF THE DRAWINGS

FIG. 1 shows a data storage enclosure back panel and a disk drive carried by a standard portable disk drive carrier and adapted for conventional hot-plug applications;

FIG. 2 shows a data storage enclosure back panel and a portable disk drive carrier according to the preferred embodiment of this invention having power control circuitry and a serial-to-parallel data converter by which the carrier is adapted for hot-plug applications while avoiding the occurrence of current surges and minimizing the damage associated therewith; and

FIG. 3 shows details of the power control circuitry that is located on the disk drive carrier of FIG. 2.

### DETAILED DESCRIPTION

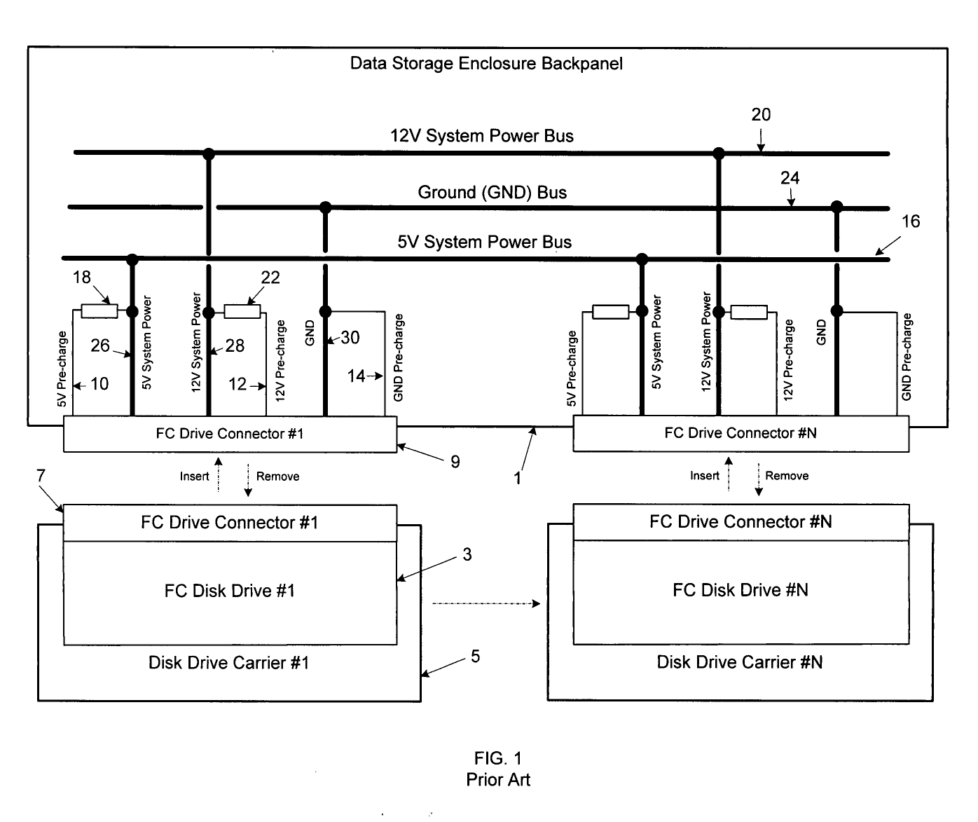

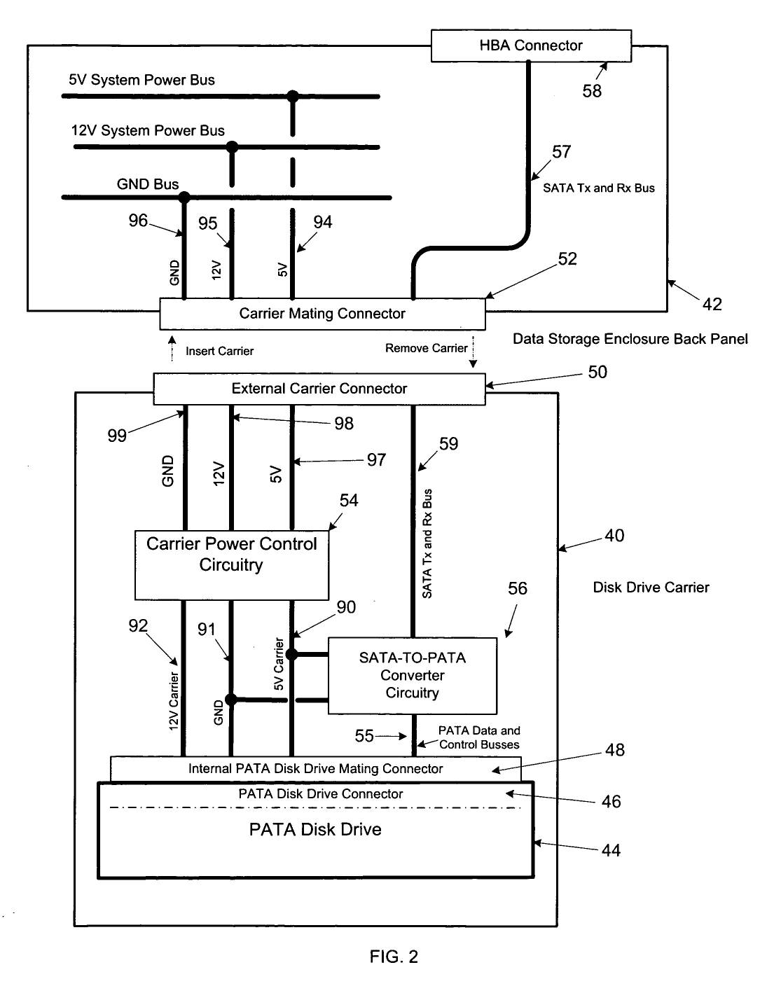

FIG. 2 of the drawings shows a portable disk drive carrier 40 having power control circuitry and a serial-to-parallel data converter, whereby the carrier 40 is adapted for hot-plug applications, while avoiding the problems described above while referring to FIG. 1. To accomplish the foregoing, the disk drive carrier 40 is interfaced with and hot-pluggable from a data storage enclosure back panel 42 that is adapted to accommodate carrier 40. The disk drive carrier 40 of FIG. 2 includes, for example, a parallel ATA (PATA) disk drive 44 having a disk drive connector 46 that is coupled to a corresponding disk drive mating connector 48 by which the disk drive 44 communicates with disk drive carrier 40. However, it is to be understood that the disk drive 44 may or may not be capable of a hot-plug connection in and of itself. Except for repair or replacement, the disk drive 44 will remain housed within its carrier 40 at all times. Once installed, the disk drive 44 is not intended to be hot-pluggable from carrier 40.

The disk drive carrier 40 also includes an external carrier connector 50 to be detachably coupled to a corresponding carrier mating connector 52 at the back panel 42. To enable hot-plug operation from the back panel 42 with the soon to be described advantages of the present improvement, the disk drive carrier 40 is provided with carrier power control circuitry 54 and serial-to-parallel (SATA-to-PATA) converter circuitry 56.

A host bus adapter (not shown) accesses the disk drive 44 that is installed on disk drive carrier 40 by way of a host bus adapter (HBA) connector 58 that is located on the data storage enclosure back panel 42. In this case, the host bus adapter is a Serial ATA (SATA) adapter. Therefore, the carrier 40 is required to have the aforementioned SATA-to-PATA converter circuitry 56. The HBA connector 58 communicates with the carrier mating connector 52 at back panel 42 by way of a SATA Tx and Rx bus 57. Likewise, the SATA-to-PATA converter circuitry 56 communicates with the external carrier connector 50 of carrier 40 by way of an additional SATA Tx and Rx bus 59. The SATA-to-PATA converter circuitry 56 also communicates with the internal disk drive mating connector 48 of carrier 40 by way of data and control buses 55.

Unlike the conventional hot-plug technique described while referring to FIG. 1, it is not necessary to have long pre-charge power pins at the disk drive mating connector (designated 9 in FIG. 1) located at the back panel (designated 1) for charging up the corresponding long pre-charge power pins at the disk drive connector (designated 7). That is, in FIG. 2, the disk drive power pins are not directly connected to the complementary power pins at the back panel. The power pins of the disk drive connector 46 of disk drive 44 are otherwise connected to the power pins at the disk drive mating connector 48 rather than to the power pins of the external carrier connector 50. In fact, the disk drive (e.g., PATA disk drive 44) may not even have long pre-charged power pins.

The disk drive 44 of FIG. 2 is powered from the output of the carrier power control circuitry 54 via the disk drive mating connector 48 and the opposing disk drive connector 46. More particularly, the output of the power control circuitry 54 supplies the required power to the PATA disk drive 44 only after the external carrier connector 50 of the disk drive carrier 40 has been coupled to its opposing mating connector 52 at the back panel 42 and after the expiration of a predetermined time delay following the successful interface of carrier 40 with back panel 42.

As previously explained, the SATA-to-PATA converter circuitry 56 on disk drive carrier 40 is required in order for the PATA disk drive 44 to be accessed by the SATA host bus adapter at HBA connector 58. A SATA host bus adapter is normally designed to interface (i.e., to communicate with and to store and retrieve disk data) to SATA disk drives rather than the PATA disk drive 44 as shown in FIG. 2. Therefore, the SATA-to-PATA converter circuitry 56 is necessary in this case to convert the serial differential signal of a SATA disk drive to the 16-bit parallel data of a PATA disk drive.

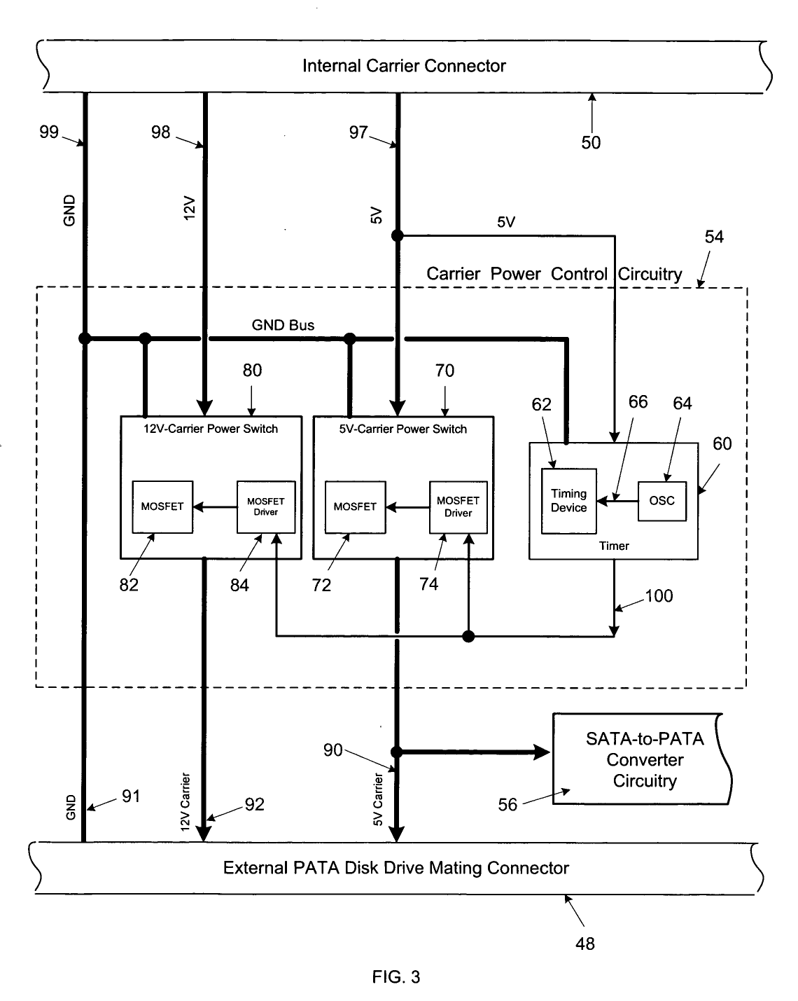

The details of the carrier power control circuitry 54 associated with disk drive carrier 40 are now explained while referring concurrently to FIGS. 2 and 3 of the drawings. As is best shown in FIG. 3, power control circuitry 54 includes a timer 60, a 5 volt carrier power switch 70 and a 12 volt carrier power switch 80. The timer 60 includes a timing device 62 and an oscillator 64. The oscillator 64 provides the timing device 62 with a reference clock signal 66.

The 5 volt carrier power switch 70 of the carrier power control circuitry 54 includes a MOSFET transistor device 72 and a MOSFET driver 74. The MOSFET driver 74 is coupled to MOSFET transistor device 72 to control the operation (i.e., state) thereof. As will soon be described, the MOSFET transistor device 72 functions as an electronic switch by which to enable 5 volt power to be supplied to disk drive 44 from the 5 volt system power bus at back panel 42 by way of the external carrier connector 50 of disk drive carrier 40, the 5 volt power pin 97 thereof, a 5 volt carrier 90, and the disk drive mating connector 48 that is coupled in mating engagement with the opposing disk drive connector 46.

The 12 volt carrier power control switch 80 of the carrier power control circuitry 54 also includes a MOSFET transistor device 82 and a MOSFET driver 84. The MOSFET driver 84 is coupled to MOSFET transistor device 82 to control the operation (i.e., state) thereof. As will also be described, the MOSFET transistor device 82 functions as an electronic switch by which to enable 12 volt power to be supplied to disk drive 44 from the 12 volt system power bus by way of the external carrier connector 50 of disk drive carrier 40, the 12 volt power pin 98 thereof, a 12 volt carrier 92, and the disk drive mating connector 48 that is coupled in mating engagement with the opposing disk drive connector 46.

The carrier power control circuitry 54 provides two controlled output voltages from the 5 volt power switch 70 via the 5 volt carrier 90 and from the 12 volt power switch 80 via the 12 volt carrier 92. The 5 volt carrier 90 feeds each of the installed PATA disk drive 44 and the SATA-to-PATA converter circuitry 56, and the 12 volt carrier 92 feeds PATA disk drive 44. With the disk drive carrier 40 coupled to the back panel 42, a continuous ground path is established from the GND bus at back panel 42 to the PATA disk drive 44 by way of the ground power pins 96 and 99 of the opposing connectors 52 and 50 and a GND carrier 91 that runs between the power control circuitry 54 and disk drive 44.

The operation of the carrier power control circuitry 54 of disk drive carrier 40 is now disclosed while continuing to refer to FIGS. 2 and 3 of the drawings. Unlike the conventional hot-plug technique illustrated in FIG. 1, the external carrier connector 50 of disk drive carrier 40 and the carrier mating connector 52 at the data storage enclosure back panel 42 do not require long pre-charge power pins. Thus, during the moment of contact between the external carrier connector 50 and its opposing carrier mating connector 52, the current on the 5 volt power pin 94 and the current on the 12 volt power pin 95 of the carrier mating connector 52 of FIG. 2 do not immediately flow through the carrier power control circuitry 54 of disk drive carrier 40. In this case, both the 5 volt carrier power switch 70 and the 12 volt carrier power switch 80 of FIG. 3 are initially disabled (i.e., the drivers 74 and 84 force MOSFET transistor switches 72 and 82 to an off or non-conductive state).

Despite the 5 and 12 volt carrier power switches 70 and 80 being disabled during initial contact between the opposing connectors 50 and 52, current will still flow into the timer 60 by way of the 5 volt power pin 94 of carrier mating connector 52 and the 5 volt power pin 97 of external carrier connector 50. The magnitude of the 5 volt current flowing to timer 60 is small relative to the disk drive current (i.e., micro-amps on one hand and amps on the other). In this regard, the timer 60 is selected so as to be capable of operating at low voltage conditions (e.g., about half the 5 volts to be provided by power pins 94 and 97) and low current (e.g., about 200 microamps). Therefore, any current surge will be reduced to a level that is sufficiently low so as to avoid damaging the connector pins 94 and 97 at back panel 42 and disk drive carrier 40 during the initial contact therebetween. By way of example only, the timing device 62 of timer 60 is a commercially available timer, such as Part No. MIC1555 manufactured by Micrel, Inc. that is capable of operating at a low voltage (e.g., 2.7 volts) and a low current (e.g., about 200 microamps).

When the input voltage at the 5 volt power pin 94 of carrier mating connector 52 rises to the operating voltage required by timer 60 (e.g., about 2.7 volts), the timing function is initiated. That is to say, the timing device 62 of timer 60 counts the number of reference clock signals 66 that are generated by oscillator 64 during a predetermined time. A suitable time (e.g., 1.0 seconds) to count the reference clock signals 66 is chosen to be sufficient to allow any bouncing motion of the contact pins at the opposing mating connectors 50 and 52 to subside.

Prior to the time that the 5 volt and 12 volt power pins 97 and 98 of external carrier connector 50 reach their full voltage levels at the input to the 5 and 12 volt carrier power switches 70 and 80, the timer 60 disables switches 70 and 80 by means of supplying a SW-DISABLE signal on signal line 100 to each of the MOSFET drivers 74 and 84, whereby the MOSFET transistor switches 72 and 82 are turned off. The SW-DISABLE signal in this case is a low voltage TTL (transistor-to-transistor logic) signal.

Following the elapsed time period (e.g., 1.0 seconds) during which the timing device 62 of timer 60 is counting reference clock signals 66, the timer 60 supplies a high voltage SW-ENABLE TTL signal on signal line 100, such that the 5 volt and 12 volt carrier power switches 70 and 80 are now enabled (e.g., MOSFET drivers 74 and 84 cause MOSFET transistor switches 72 and 82 to be turned on). In other words, drivers 74 and 84 generate a sufficient gate voltage, whereby MOSFET transistor switches 72 and 82 are now rendered conductive.

Once the 5 volt and 12 volt carrier power switches 70 and 80 of the carrier power control circuitry 54 at disk drive carrier 40 have been enabled by the high voltage SW-ENABLE TTL signal on signal line 100, the 5 volt and 12 volt carriers 90 and 92 are electrically connected (via respective carrier power switches 70 and 80) to the 5 volt and 12 volt power pins 97 and 98 of the external carrier connector 50 and to the corresponding 5 volt and 12 volt system power buses at back panel 42 via the 5 volt and 12 volt power pins 94 and 95 of the carrier mating connector 52. Accordingly, the power that is required by the PATA disk drive 44 and the SATA-to-PATA converter circuitry 56 is now supplied to support normal disk drive operation.

It may be appreciated that the power control circuitry 54 is located entirely on the portable disk drive carrier 40. Therefore, when a repair to circuitry 40 is required, it is not necessary to power down the entire data storage system and to spend time making a time consuming disassembly as would be the case if the power control circuitry were otherwise located on the back panel 42 of the data system enclosure. By virtue of the present invention, it is only necessary to remove the defective disk drive carrier for repair or replacement without having to remove the back panel 42 to be sent out for service during which the entire system would remain disconnected from its network.

1. A data storage system interfaced with a host computer and comprising:
a portable disk drive carrier adapted for hot-plug operation and including a disk drive mounted on said disk drive carrier and an external carrier connector; and
a data storage system enclosure within which system power buses are housed, said data storage enclosure having a carrier mating connector to which the external carrier connector of said portable disk drive carrier is detachably coupled, whereby electrical power from the system power buses is supplied to the disk drive of said disk drive carrier to enable said disk drive to be accessed by said host computer,
said portable disk drive carrier also including power control circuitry located between the external carrier connector of said disk drive carrier and the disk drive mounted on said disk drive carrier to control the power supplied thereto, said power control circuitry including a time delay by which power is supplied from the power buses at said data storage system enclosure to the disk drive at said disk drive carrier a particular time after the external carrier connector of said disk drive carrier is coupled to the carrier mating connector of said data storage system enclosure.

2. The data storage system recited in claim 1, wherein said portable disk drive carrier also includes an internal disk drive mating connector and said disk drive includes a disk drive connector attached to said internal disk drive mating connector, whereby said disk drive is electrically interconnected with the external carrier connector of said disk drive carrier, the power control circuitry of said disk drive carrier being connected to said disk drive by way of the internal disk drive mating connector of said disk drive carrier and the disk drive connector of said disk drive.

3. The data storage system recited in claim 1, wherein the power control circuitry of said portable disk drive carrier has a timer by which to establish said time delay before power is supplied to the disk drive at said disk drive carrier from the power buses at said data storage system enclosure.

4. The data storage system recited in claim 3, wherein said power control circuitry includes an electronic switch located between one of the power buses at said data storage system enclosure and the disk drive at said portable disk drive carrier, said timer generating an output signal after said time delay by which to close said electronic switch and thereby connect the one of said power buses to said disk drive to supply power thereto.

5. The data storage system recited in claim 4, wherein said electronic switch of said power control circuitry is a field effect transistor, the output signal generated by said timer after said time delay enabling said field effect transistor and thereby connecting the one of said power buses to said disk drive.

6. The data storage system recited in claim 3, wherein said power control circuitry includes a first electronic switch located between a 5 volt power bus at said data storage system enclosure and the disk drive at said portable disk drive carrier and a second electronic switch located between a 12 volt power bus at said data storage system enclosure and the disk drive at said portable disk drive carrier, said timer generating an output signal after said time delay by which to close said first and second electronic switches and thereby connect said 5 and 12 volt power buses to said disk drive to supply power thereto.

7. The data storage system recited in claim 6, wherein the 5 volt power bus at said data storage system enclosure is connected to the timer of the power control circuitry of said portable disk drive carrier to provide power to said timer and thereby initiate said time delay after the external carrier connector of said disk drive carrier is coupled to the carrier mating connector of said data storage system enclosure.

8. The data storage system recited in claim 6, wherein each of said first and second electronic switches of said power control circuitry is a field effect transistor, the output signal generated by said timer after said time delay enabling said first and second field effect transistors and thereby respectively connecting said 5 volt and 12 volt power buses to said disk drive.

9. The data storage system recited in claim 8, said disk drive carrier also including 5 volt and 12 volt carriers respectively connected between said first and second field effect transistors of said power control circuitry and said disk drive for supplying 5 volt and 12 volt input power to said disk drive from said 5 volt and 12 volt power buses.

10. The data storage system recited in claim 9, wherein the disk drive of said portable disk drive carrier is a parallel ATA (PATA) disk drive, said PATA disk drive being accessed by the host computer at a host bus adapter located at said data storage system enclosure.

11. The data storage system recited in claim 10, said portable disk drive carrier also including a serial ATA-to-parallel ATA converter connected between said PATA disk drive and said host bus adapter, whereby parallel data is transmitted from said disk drive to said adapter.

12. The data storage system recited in claim 11, wherein said serial ATA-to-parallel ATA converter is connected to the 5 volt carrier of said portable disk drive carrier so as to be powered by the 5 volt power bus at said data storage system enclosure.

13. A portable disk drive carrier enclosing a disk drive and being adapter for hot-plug connection to a power supply to provide power to the disk drive and thereby enable the disk drive to be accessed by a host computer, said transportable disk drive carrier including a power control circuit having a timer by which to cause the power being provided to the disk drive from the power supply to be delayed until a particular time has elapsed after the connection of said disk drive carrier to said power supply.

14. The portable disk drive carrier recited in claim 13, wherein the power supply to which said disk drive carrier is hot-plug connected includes at least one power bus, the power control circuitry of said disk drive carrier also including at least one switch connected between said power bus and the disk drive, the timer of said power control circuit generating an output signal after said particular time has elapsed for closing said switch and thereby enabling power to be provided from said power bus to said disk drive.

15. The portable disk drive carrier recited in claim 14, wherein said at least one switch is an electrical power control switch.

16. The portable disk drive carrier recited in claim 13, wherein the power supply to which said disk drive carrier is hot-plug connected includes a 5 volt power bus and a 12 volt power bus, the power control circuit of said disk drive carrier also including first and second power control switches respectively connected between said 5 volt and 12 volt power buses and said disk drive, the timer of said power control circuit generating an output signal after said particular time has elapsed for closing said first and second power control switches and thereby enabling power to be provided from the 5 volt and 12 volt power buses to said disk drive.

17. The portable disk drive carrier recited in claim 16, wherein each of said first and second power control switches is a field effect transistor.

18. The portable disk drive carrier recited in claim 16, wherein power is supplied to the timer of said power control circuit from the 5 volt power bus of the power supply for causing said timer to begin timing following the connection of said disk drive carrier to said power supply.
